(19) United States
(12) Patent Application Publication
(10) Pub. No.: US 2006/0213058 A1
(43) Pub. Date: Sep. 28, 2006

(54) Circuit board for surface-mount device to be mounted thereon

(76) Inventor: Shih-Fang Lee, Hsin-Chu (TW)

Correspondence Address: LAW OFFICES OF JOHN CHUPA & ASSOCIATES, P.C., 28535 ORCHARD LAKE ROAD, SUITE 50, FARMINGTON HILLS, MI, 48334, US

(21) Appl. No.: 11/216,827

(22) Filed: Aug. 31, 2005

(30) Foreign Application Priority Data
Mar. 25, 2005 (TW) 094109480

(51) Int. Cl. H05K 3/34; H01R 9/00; G01R 31/28; H01L 21/66; H01L 21/00

(52) U.S. Cl. 29/840; 29/593; 438/15; 438/106; 29/842

(57) ABSTRACT

A circuit board for a surface-mount device to be mounted thereon is provided. The surface-mount device includes a set of first pins and a set of second pins. The circuit board includes a substrate, a set of first conductors, a set of second conductors, and a hole. The hole is formed through the substrate and adjacent to the set of second conductors. The mounting of the surface-mount device is performed by the steps of: (a) disposing the surface-mount device on the substrate; (b) soldering the set of first pins on the set of first conductors and the set of second pins on the set of second conductors by reflowing; (c) checking whether each second pin is electrically-connected with the corresponding second conductor; and (d) re-soldering the second pin that is electrically-disconnected with the corresponding second conductor by a welder through the hole.

### BACKGROUND OF THE INVENTION

1. Field of the invention

This invention relates to a circuit board. More specifically, the invention relates to a circuit board for a surface-mount device to be mounted thereon.

2. Description of the prior art

Over the last decade the electronics industry has made many advances with respect to electronic components. One of the significant advances is the introduction of the Surface-Mount Device (SMD) or surface mount technology. Flip chips, ball grid arrays, chip scale packages, chip resistors and chip capacitors are examples of SMDs. SMDs allow electrical components to be mounted on one side of a PCB, without requiring the leads of the components to be inserted through the printed circuit board (PCB) and soldered to the reverse side of the PCB, (i.e., an older method of mounting components to PCBs referred to as through-hole technology). An SMD component has small metalized pins (terminals or leads) connected to its body, which correspond to solder pads (or lands) located on the surface of the PCB. Typically the PCB is run through a solder-paste machine (or screen printer), which puts a proper amount of solder on the solder pads of the PCB. Then, the component is placed on the PCB such that the metalized pins of the component are aligned with the solder pads of the PCB. Then, the PCB is sent through a re-flow oven to heat the solder paste and solder the component leads to the PCB solder pads. Thus, the metalized pins of the component have electrically-connections with the solder pads of the PCB. The advantage of surface mount technology is that both sides of the PCB can now be populated by electronic components, respectively. Therefore, the using efficiency of the PCB is greatly raised.

As known by people skilled in this art, another technology for saving areas of PCBs is making some connectors in the form of dual stack. Please refer to FIG. 1A and FIG. 1B. FIG. 1A shows the single stack connector 20 and single stack connector 30 respectively soldered on the circuit board 10A. The signal input 20A of the single stack connector 20 is electrically-connected to certain solder pad on the circuit board 10A through the metalized pin 20B; the signal input 30A of the single stack connector 30 is electrically-connected to the other solder pad on the circuit board 10A through the metalized pin 30B. FIG. 1B shows the dual stack connector 40 soldered on the circuit board 10B. The first signal input 40A of the dual stack connector 40 is electrically-connected to certain solder pad on the circuit board 10B through the metalized pin 40C; the second signal input 40B of the dual stack connector 40 is electrically-connected to the other solder pad on the circuit board 10B through the metalized pin 40D. As shown in FIG. 1A and FIG. 1B, the area occupied by the dual stack connector 40 is smaller than the sum of area occupied by the single stack connector 20 and single stack connector 30; on the other hand, the dual stack connector 40 can provide the same amount of signal inputs as the sum of amount provided by the single stack connector 20 and single stack connector 30.

As shown in FIG. 1B, the metalized pin 40D is located in the inner side of the metalized pin 40C; hence, surface mount technology is more workable than traditional soldering by welders. However, after being soldered on the circuit board 10B, once the metalized pin 40D is found as electrically-disconnected with its corresponding solder pad, i.e., a soldering failure occurs, the problem cannot be solved by merely re-soldering the metalized pin 40D by a welder. The whole PCB should be sent through a re-flow oven again. The aforementioned remedy not only is inefficient, but may also destroy the other components that have been well soldered on the PCB.

In actual applications, dual row connectors have similar structures as dual stack connectors. The aforesaid problem could occur in soldering processes of dual row connectors.

Accordingly, this invention provides a circuit board for a SMD to be mounted thereon and a method for soldering the SMD to solve the aforementioned problem.

### SUMMARY OF THE INVENTION

The main purpose of this invention is providing a circuit board for a surface-mount device (SMD) to be mounted thereon. The SMD includes a set of first pins and a set of second pins.

One preferred embodiment according to this invention is a circuit board including a substrate, a set of first conductors, a set of second conductors, and a hole. The substrate has a top surface and a bottom surface opposite to the top surface. The set of first conductors is formed on the top surface of the substrate, for providing connection to the set of first pins; each of the first conductors corresponding to one of the first pins. The set of second conductors is formed on the top surface of the substrate, for providing connection to the set of second pins; each of the second conductors corresponding to one of the second pins. The hole is formed through the substrate and adjacent to the set of second conductors.

In this preferred embodiment, the mounting of the SMD on the circuit board is performed by the steps of: (a) disposing the SMD on the top surface of the substrate such that the set of first pins is aligned with the set of first conductors and the set of second pins is aligned with the set of second conductors; (b) soldering the set of first pins on the set of first conductors and the set of second pins on the set of second conductors by reflowing; (c) checking whether each of the second pins is electrically-connected with the corresponding second conductor; and (d) re-soldering the second pin that is electrically-disconnected with the corresponding second conductor by a welder, wherein during the process of re-soldering, the welder passes from the bottom surface to the top surface through the hole.

The advantage and spirit of the invention may be understood by the following recitations together with the appended drawings.

### BRIEF DESCRIPTION OF THE APPENDED DRAWINGS

FIG. 1A shows the single stack connector 20 and single stack connector 30 respectively soldered on the circuit board 10A.

FIG. 1B shows the dual stack connector 40 soldered on the circuit board 10B.

FIG. 2 shows the bottom of a dual stack SATA connector.

FIG. 3 shows the first preferred embodiment of this invention.

FIG. 4 shows the flow chart of how to solder a SMD on the circuit board in the first preferred embodiment of this invention.

FIG. 5 shows the second preferred embodiment of this invention.

FIG. 6 shows how to solder the second pin by a welder through the hole of the circuit board.

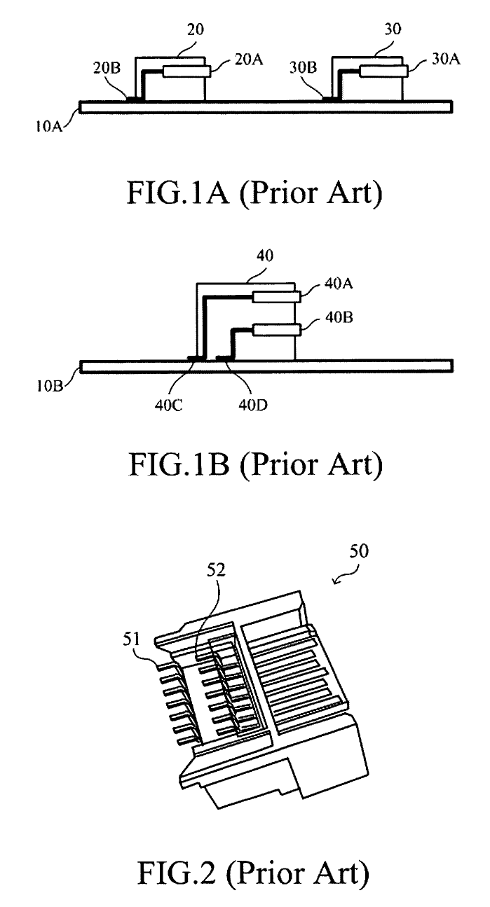

### DETAILED DESCRIPTION OF THE INVENTION

The main purpose of this invention is providing a circuit board for a SMD to be mounted thereon and a method for soldering the SMD. In actual applications, the SMD can be a dual stack connector or a dual row connector.

In the first preferred embodiment according to this invention, the SMD is a dual stack serial advanced technology attachment (SATA) connector. Please refer to FIG. 2. FIG.2 shows the bottom of the dual stack SATA connector 50. The dual stack SATA connector 50 includes a set of first pins 51 and a set of second pins 52. The set of second pins 52 is located in the inner side of the dual stack SATA connector 50 corresponding to the set of first pins 51.

The first preferred embodiment according to this invention is a circuit board including a substrate, a set of first conductors, a set of second conductors, and a hole. The substrate has a top surface and a bottom surface opposite to the top surface. The set of first conductors is formed on the top surface of the substrate, for providing connection to the set of first pins; each of the first conductors corresponding to one of the first pins. The set of second conductors is formed on the top surface of the substrate, for providing connection to the set of second pins; each of the second conductors corresponding to one of the second pins. The hole is formed through the substrate and adjacent to the set of second conductors.

This invention first solders the dual stack connector on the circuit board by traditional re-soldering method in surface mount technologies. Once a soldering failure of the set of second pins 52 occurs, users can re-soldering the failed second pin 52 by a welder through the hole.

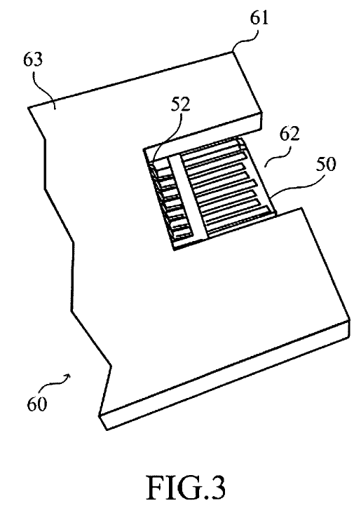

Please refer to FIG. 3. FIG. 3 shows the first preferred embodiment of this invention. For the convenience of explanation, only the following components are shown in the figure: the substrate 61 and the hole 62 included in the circuit board 60, the bottom surface 63, and the set of second pins 52 of the connector 50. As shown in FIG. 3, the hole 62 is adjacent to the set of second conductors such that it's more convenient for users to re-solder the failed second pin 52 by a welder through the hole 62. On the other hand, the hole 62 is formed so that the other layouts on the circuit board 60 are not affected.

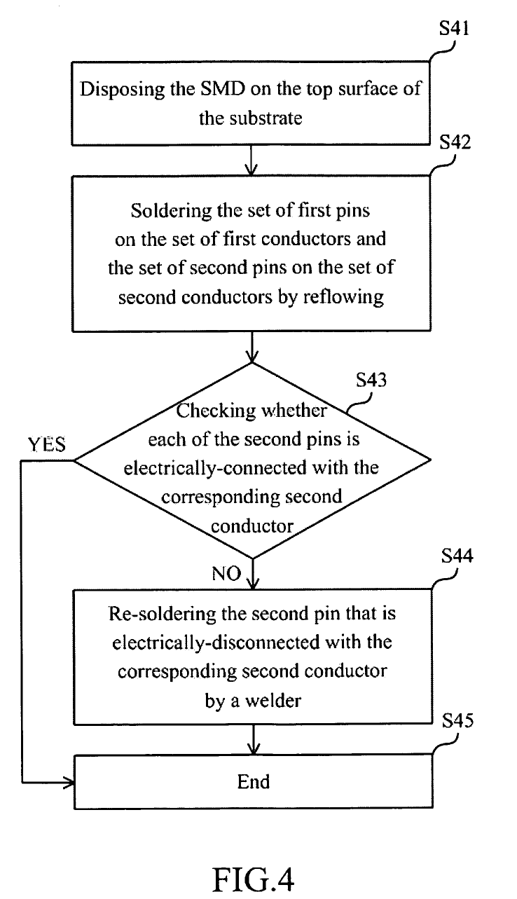

FIG. 4 shows the flow chart of how to solder the connector 50 on the circuit board 60 in the first preferred embodiment of this invention. Step S41 is disposing the SMD on the top surface of the substrate such that the set of first pins 51 is aligned with the set of first conductors and the set of second pins 52 is aligned with the set of second conductors. Step S42 is soldering the set of first pins 51 on the set of first conductors and the set of second pins 52 on the set of second conductors by reflowing. Step S43 is checking whether each of the second pins is electrically-connected with the corresponding second conductor. If the checking result of step S43 is YES, step S45 is performed to end the flow; if the checking result of step S43 is NO, step S44 is performed. Step S44 is re-soldering the second pin 52 that is electrically-disconnected with the corresponding second conductor by a welder, wherein during the process of re-soldering, the welder passes from the bottom surface 63 to the top surface through the hole 62.

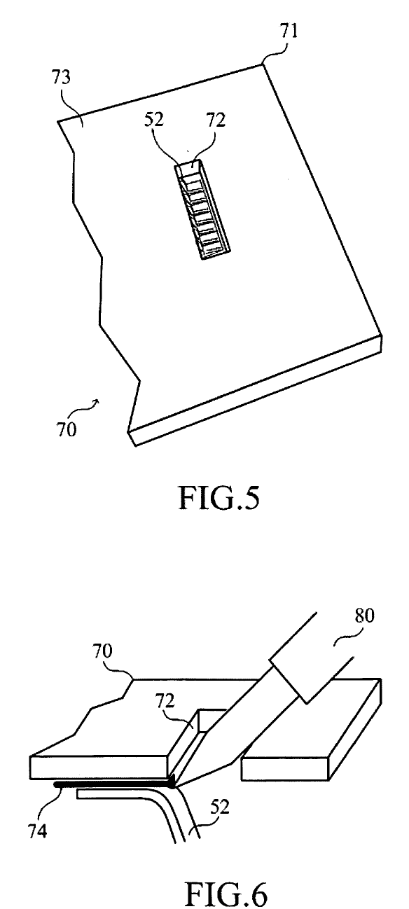

Please refer to FIG. 5. FIG. 5 shows the second preferred embodiment of this invention. For the convenience of explanation, only the following components are shown in the figure: the substrate 71 and the hole 72 included in the circuit board 70, the bottom surface 73, and the set of second pins 52 of the connector 50. In comparison with the first preferred embodiment, the hole 72 included in the circuit board 70 is smaller than the hole 62 included in the circuit board 60. The embodiment shown in FIG. 5 points out that in actual application, as long as the hole can provide sufficient space for a welder to pass through, the circuit board conforms to the main spirit of this invention. That is to say, the shape and size of a whole is not a important feature of this invention.

FIG. 6 shows how to solder the second pin 52 by a welder 80 through the hole 72 of the circuit board 70. As shown in FIG. 6, the welder 80 passes from the bottom surface 73 to the space between the second pin 52 and the set of second conductors 74 through the hole 72.

According to this invention, once a soldering failure of the set of second pins 52 occurs, users can re-soldering the failed second pin 52 by a welder through the hole instead of re-flowing the whole circuit board. Accordingly, the efficiency of soldering process can be substantially raised. Besides, the circuit board and soldering method can also be applied to other SMDs other than dual stack connectors and dual row connectors.

The third preferred embodiment of this invention is a method for soldering a SMD on a circuit board. The circuit board includes a substrate having a top surface and a bottom surface opposite to the top surface. The SMD includes a pin to be soldered on a first position at the top surface of the substrate. The method includes the steps of: (a) forming a hole at a second position at the top surface and through the substrate, wherein the second position being adjacent to the first position; (b) disposing the SMD on the top surface of the substrate such that the pin is aligned with the first position; and (c) soldering the pin on the first position with a welder, wherein during the process of soldering, the welder passes from the bottom surface to the top surface through the hole.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A circuit board for a surface-mount device (SMD) to be mounted thereon, the SMD comprising a set of first pins and a set of second pins, said circuit board comprising:
a substrate having a top surface and a bottom surface opposite to the top surface;
a set of first conductors, formed on the top surface of the substrate, for providing connection to the set of first pins, each of the first conductors corresponding to one of the first pins;
a set of second conductors, formed on the top surface of the substrate, for providing connection to the set of second pins, each of the second conductors corresponding to one of the second pins; and
a hole, formed through the substrate and adjacent to the set of second conductors;
wherein the mounting of the SMD on said circuit board is performed by the steps of:
(a) disposing the SMD on the top surface of the substrate such that the set of first pins is aligned with the set of first conductors and the set of second pins is aligned with the set of second conductors;
(b) soldering the set of first pins on the set of first conductors and the set of second pins on the set of second conductors by reflowing;
(c) checking whether each of the second pins is electrically-connected with the corresponding second conductor, if NO, executing step (d); and
(d) re-soldering the second pin that is electrically-disconnected with the corresponding second conductor by a welder, wherein during the process of re-soldering, the welder passes from the bottom surface to the top surface through said hole.

2. The circuit board of claim 1, wherein the SMD is a dual stack connector.

3. The circuit board of claim 2, wherein the dual stack connector is a dual stack serial ATA (SATA) connector.

4. The circuit board of claim 1, wherein the SMD is a dual row connector.

5. A method for soldering a surface-mount device (SMD) on a circuit board, the circuit board comprising a substrate having a top surface and a bottom surface opposite to the top surface, the SMD comprising a set of pins to be soldered on a set of conductors formed on the top surface of the circuit board, each pin being respectively corresponding to one conductor, said method comprising the steps 6f:
(a) forming a hole through the substrate of the circuit board and adjacent to the set of conductors;
(b) disposing the SMD on the top surface of the substrate such that the set of pins is aligned with the set of conductors;
(c) soldering the set of pins on the set of conductors by reflowing;
(d) checking whether each pin is electrically-connected with the corresponding conductor, if NO, executing step (e); and
(e) re-soldering the pin that is electrically-disconnected with the corresponding conductor by a welder, wherein during the process of re-soldering, the welder passes from the bottom surface to the top surface through said hole.

6. The method of claim 5, wherein the SMD is a dual stack connector.

7. The method of claim 6, wherein the dual stack connector is a dual stack serial ATA (SATA) connector.

8. The method of claim 5, wherein the SMD is a dual row connector.

9. A method for soldering a surface-mount device (SMD) on a circuit board, the circuit board comprising a substrate having a top surface and a bottom surface opposite to the top surface, the SMD comprising a pin to be soldered on a first position at the top surface of the substrate, said method comprising the steps of:
forming a hole at a second position at the top surface and through the substrate, said second position being adjacent to the first position;
disposing the SMD on the top surface of the substrate such that the pin is aligned with the first position; and
soldering the pin on said first position with a welder, wherein during the process of soldering, the welder passes from the bottom surface to the top surface through said hole.

10. The method of claim 9, wherein the SMD is a dual stack connector.

11. The method of claim 10, wherein the dual stack connector is a dual stack serial ATA (SATA) connector.

12. The method of claim 9, wherein the SMD is a dual row connector.
